(19) United States
(12) Patent Application Publication
(10) Pub. No.: US 2019/0067861 A1
(43) Pub. Date: Feb. 28, 2019

(54) LOW INDUCTANCE ELECTRICAL CONTACT ASSEMBLY

(71) Applicant: JF MICROTECHNOLOGY SDN. BHD., Petaling Jaya (MY)

(72) Inventors: Wei Kuong FOONG, Petaling Jaya (MY); Kok Sing GOH, Petaling Jaya (MY); Shamal MUNDIYATH, Petaling Jaya (MY); Eng Kiat LEE, Petaling Jaya (MY)

(73) Assignee: JF MICROTECHNOLOGY SDN. BHD., Petaling Jaya (MY)

(21) Appl. No.: 16/115,288

(22) Filed: Aug. 28, 2018

(30) Foreign Application Priority Data
Aug. 28, 2017 (MY) PI 2017703169

(51) Int. Cl. H01R 13/405; H01R 13/504; G01R 1/073

(52) U.S. Cl. CPC H01R 13/405; G01R 1/07307; H01R 13/504

(57) ABSTRACT

An electrical contact test assembly that has a small size, a very low inductance, is able to handle high frequency and high current testing, and one that is easy to assemble, handle and maintain. An electrical contact assembly that comprises a shorter length of contact achieved by sandwiching an inner holder in between two rows of contacts and keeping them together via an adhesive between each of the two rows of contacts and the inner holder. In this way, very small sizes of contacts are more easily assembled and handled. The low inductance then allows for high frequency testing. An electrical contact assembly that comprises a one-piece contact without the complexity of other designs such as screws, springs, etc, allowing higher currents and tri-temperature testing.

### FIELD OF INVENTION

The present invention relates to an electrical contact assembly in an integrated circuit testing apparatus, and specifically to one that has a low inductance in a small sized contact that is able to withstand high currents and high frequency testing.

### BACKGROUND OF INVENTION

Currently available standard Kelvin contact assemblies used in integrated circuit (IC) testing apparatuses are typically in the size range of 3 mm and larger. This is to allow for easier handling of the contacts during installation, assembly, maintenance and rebuilding. At such sizes, the inductance of the contacts are typically 3 nH or higher. A higher inductance characteristic does not allow for testing with higher frequencies, due to the electro-magnetic interference that will result. Certain applications, namely: the Internet of things (smart homes, cars, etc) require IC chips that operate at high frequencies, and therefore testing at those frequencies.

What is needed in the art is a smaller electrical contact with a low inductance that is still easy to handle, assemble and maintain, and that allows testing at high frequencies (20 GHz or more).

Conversely, there are designs such as spring probes that allow for very small sizes of contacts, down below 3 mm. However, these type of contacts are complex designs with at least 3 separate parts, and are therefore more prone to faults and are also harder to assemble, especially at small sizes. Another downside to spring probe designs is their inability to handle high currents. Certain applications in the automotive industry require ICs that operate with high currents. Furthermore, the complex design on these spring probe type contacts make them less than ideal for tri-temperature testing. The screws, dowel pins and other non-homogeneous parts in the contacts cause changes in the contact's electrical properties when exposed to extreme temperatures, which in turn results in malfunctioning of the contact.

What is then also needed in the art is a low inductance electrical contact that has a simpler and more robust design and that allows testing at high currents and high frequencies.

Yet another type of contact design employs rigid pins along with a compressible elastomer, wherein the pins typically rock around a point when the device-under-test (DUT) is engaged to the testing apparatus, and the elastomer provides a resistant force that rocks the pin back to its initial position. These type of contacts, while able to achieve low inductance, unfortunately are not able to handle high temperatures. At high temperatures, the elastomer is prone to break-down. Therefore, these contacts are not suitable for tri-temperature testing.

What is then also needed in the art is a low inductance electrical contact that is able to handle testing at high temperatures.

### SUMMARY OF INVENTION

The present invention seeks to overcome the aforementioned disadvantages by providing an electrical contact test assembly that has a small size, a very low inductance, is able to handle high frequency and high current testing, and one that is easy to assemble, handle and maintain at tri-temperature testing.

In a solution to the problem of contacts with high inductance, this invention provides an electrical contact assembly that comprises a shorter length of contact. This is achieved by sandwiching an inner holder in between two rows of contacts and keeping them together via an adhesive between each of the two rows of contacts and the inner holder. In this way, very small sizes of contacts are more easily assembled and handled. The low inductance then allows for high frequency testing.

In a solution to the problem of inability to handle high currents, this invention provides an electrical contact assembly that comprises a one-piece contact module without the complexity of other designs such as screws, springs, etc. This one-piece contact allows more extreme temperatures during testing, and thus tri-temperature testing is possible with this contact.

This invention thus relates to an electrical contact assembly for use in a testing apparatus, comprising: a plurality of inner pins arranged in a row, each inner pin having a vertical section; a plurality of outer pins in a row, each outer pin having a vertical section; an inner holder located in between said plurality of inner pins and said plurality of outer pins, said inner holder having a C-shaped cross-section, whereby an inner surface of the inner holder is adapted to receive a back side of said vertical section of said plurality of inner pins, and an outer surface of the inner holder is adapted to be received by a front side of said vertical section of said plurality of outer pins; and an outer holder having an inner surface adapted to receive a back side of said plurality of outer pins.

In one preferred embodiment, an adhesive is applied between the inner holder inner surface and the inner pin vertical section, such that the plurality of inner pins are joined to the inner holder. The adhesive is also applied between the inner holder outer surface and the outer pin vertical section, such that the plurality of outer pins are joined to the inner holder. The adhesive is further applied between the outer holder inner surface and the outer pin vertical section, so that the plurality of outer pins adhere to the outer holder.

Other objects and advantages will be more fully apparent from the following disclosure and appended claims.

### BRIEF DESCRIPTION OF DRAWINGS

FIG. 1 shows a cross-sectional view of a contact assembly in an embodiment of this invention.

FIG. 2 shows an exploded view of a contact assembly in an embodiment of this invention.

FIG. 3 shows a top side perpendicular view of a contact assembly in an embodiment of this invention.

FIG. 4 shows a bottom side perpendicular view of a contact assembly in an embodiment of this invention.

FIG. 5 shows an exploded side view of a contact assembly in an embodiment of this invention.

FIG. 6 shows a top view of a contact assembly in an embodiment of this invention.

### DETAILED DESCRIPTION OF INVENTION

It should be noted that the following detailed description is directed to an electrical contact assembly of an integrated circuit (IC) testing apparatus, and is not limited to any particular size or configuration but in fact a multitude of sizes and configurations within the general scope of the following description.

### LIST OF NUMBERED ELEMENTS IN FIGURES

Inner Pin (10)
Inner Pin Bottom Cantilever (13)
Inner Pin Load End (14)
Inner Pin Vertical Section (15)
Inner Pin Top Cantilever (17)
Inner Pin Device End (18)
Outer Pin (20)
Outer Pin Bottom Cantilever (23)
Outer Pin Load End (24)
Outer Pin Vertical Section (25)
Outer Pin Diagonal Section (26)
Outer Pin Top Cantilever (27)
Outer Pin Device End (28)
Inner Holder (30)
Inner Holder Inner Surface (32)
Inner Holder Outer Surface (34)
Inner Holder Elongated Holes (35)
Outer Holder (40)
Outer Holder Inner Surface (42)
Outer Holder Elongated Holes (45)

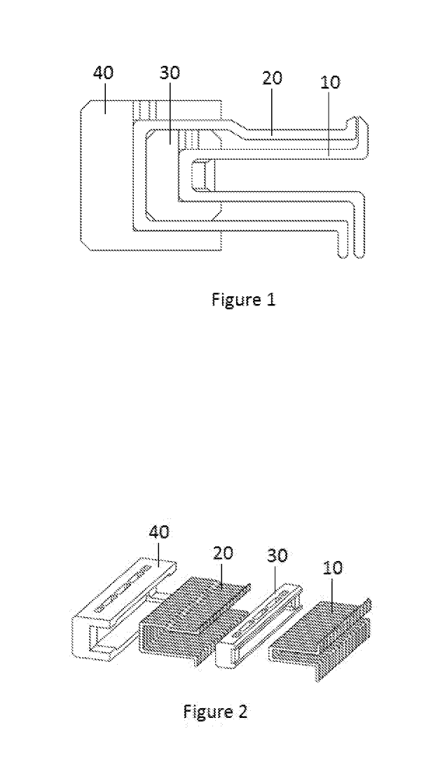

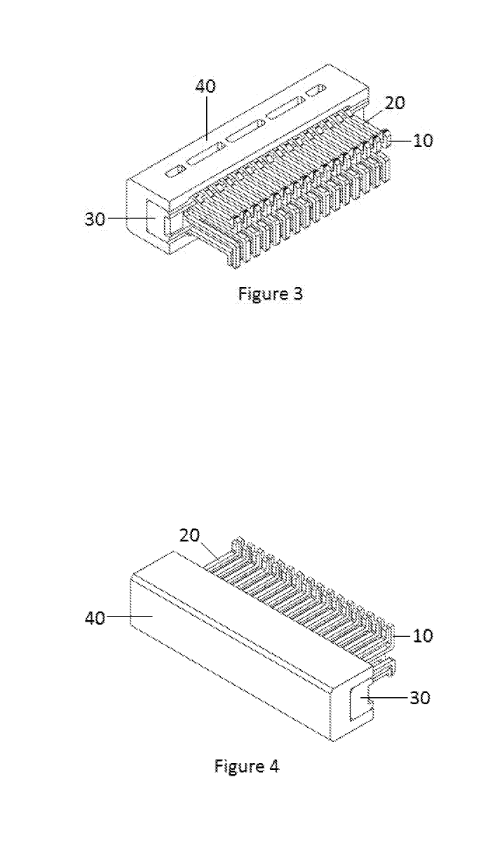

Referring to FIGS. 1 through 4, there are shown several views of a contact assembly in an embodiment of the present invention. A plurality of inner pins (10) is arranged in a row at a front end of the assembly. Each inner pin includes a C-shaped portion. An inner holder (30) having a C-shaped cross-section is located in between said row of inner pins (10) and a plurality of outer pins (20), said outer pins also arranged in a row. A front or inner surface of the inner holder (30) is adapted to fit around the said C-shaped portion of the row of inner pins (10). Likewise, each outer pin (20) also has a C-shaped portion, a front or inner surface of which fits around a back or outer surface (34) of the inner holder (30). Finally, an outer holder (40) also having a C-shaped cross-section is located behind the said row of outer pins (20), a front or inner surface of said outer holder (40) adapted to fit around said outer pin C-shaped portion.

From the different views, it is made clear how the inner pins (10), outer pins (20), inner holder (30) and outer holder (40) are assembled together to form the contact assembly of this invention. FIG. 2 shows an exploded view, which shows the components as they would be pre-assembly.

Along a top side of the inner holder (30), there is provided a series of elongated holes (35) which is located adjacently above said row of inner pins (10). Along a top side of the outer holder (40), there is also provided a series of elongated holes (45) which is located adjacently above said row of outer pins (20).

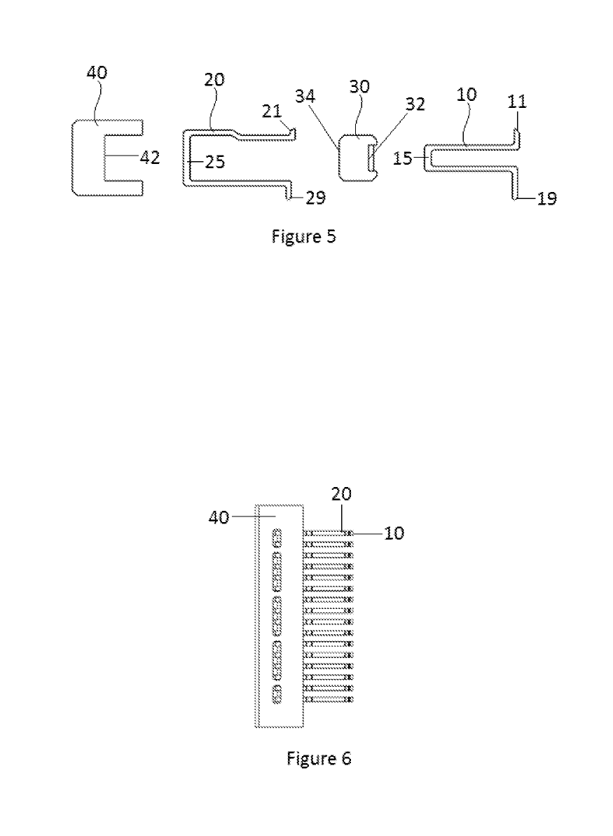

Referring to FIG. 5, there is shown an exploded cross-sectional view of the contact assembly of FIGS. 1 through 4. In this view, it is possible to see clearly how the components: inner pins (10), outer pins (20), inner holder (30) and outer holder (40) would be joined together.

In more detail, each said inner pin (10) is C-shaped with a vertical section (15) joining a horizontal bottom cantilever (13) to a horizontal top cantilever (17). At the other end of the bottom cantilever (13), a vertical load end (14) extends downwards, which during testing comes into contact with the load board of a testing apparatus. Similarly, at the other end of the top cantilever (17), a vertical device end (18) extends upwards, which during testing comes into contact with a device under test (DUT). The portion comprising part of the top cantilever (17), the vertical section (15) and part of the bottom cantilever (13) forms the so-called “C-shaped portion” of this inner pin (10) mentioned above and in relation to FIGS. 1 through 4.

Each said outer pin (20) is C-shaped with a vertical section (25) joining a horizontal bottom cantilever (23) to a horizontal top cantilever (27). At the other end of the bottom cantilever (23), a vertical load end (24) extends downwards, which during testing comes into contact with the load board of a testing apparatus. Similarly, at the other end of the top cantilever (27), a vertical device end (28) extends upwards, which during testing comes into contact with a device under test (DUT). The outer pins (20) are designed to wrap around the inner holder (30). In each outer pin (20), the top cantilever (27) is raised slightly near its middle so that there are essentially two top horizontal sections joined by a diagonal section (26). This is to facilitate wrapping snugly around the inner holder (30). The portion comprising part of the top cantilever (27), the vertical section (25) and part of the bottom cantilever (23) forms the so-called “C-shaped portion” of this outer pin (20) mentioned above and in relation to FIGS. 1 through 4.

Still referring to FIG. 5, the C-shaped inner holder (30) is shown with a front or inner surface (32) and a back or outer surface (34). It can be deduced that, upon assembly, the inner surface (32) of the inner holder encapsulates the C-shaped portion of the inner pin (10) formed by the vertical section (15), and parts of the top cantilever (17) and bottom cantilever (13). The outer surface (34) of the inner holder (30) is in turn encapsulated by the C-shaped portion of the outer pin (20) formed by the vertical section (25), and parts of the top cantilever (27) and bottom cantilever (23).

The inner holder (30) is hollowed-out with a C-shaped cross-section and an open inner face, and is designed to wrap around the vertical section (15) side of the row of inner pins (10), in order to contain said inner pins (10). The said inner holder (30) is enclosed at each end to further contain said inner pins (10). The said inner holder (30) has an inner surface (32) on the inside of the C-shape which faces and, after assembly, is flush against the inner pin vertical section (15). The inner holder (30) also has an outer surface (34) which faces outwards and, after assembly, is flush against the outer pin vertical section (25). In this way, the inner pin load end (14) and the outer pin load end (24) are side by side with, but not touching, each other. Similarly, the inner pin device end (18) and the outer pin device end (28) are also side by side with, but not touching, each other. The inner holder (30) is provided with a series of elongated holes (35) on its top side which, after assembly, is adjacently above the top cantilevers (17) of the plurality of inner pins (10).

The outer holder (40) is hollowed-out with a C-shaped cross-section and an open inner face, and is designed to wrap around the vertical section (25) side of the row of outer pins (20), in order to contain said outer pins (20). The said outer holder (40) is partially enclosed at each end to further contain said outer pins (20). The said outer holder (40) has an inner surface (42) on the inside of the C-shape which faces and, after assembly, is flush against the outer pin vertical section (25). The outer holder (40) is provided with a series of elongated holes (45) on its top side which, after assembly, is adjacently above the top cantilevers (27) of the plurality of outer pins (20).

Adhesive applied into the inner holder elongated holes (35) secures the said vertical section side of the inner pins (10) to the inner holder (30). Adhesive applied into the outer holder elongated holes (45) secures the said vertical section side of the outer pins (20) to the outer holder (40) and the inner holder (30). In a preferred embodiment, the adhesive is a non-conductive adhesive, such as epoxy. In another preferred embodiment, the adhesive is a non-conductive, tri-temp resistant adhesive.

In this way, the vertical sections (15, 25) of both inner pins (10) and outer pins (20) are secured to the inner holder (30) and the vertical section (25) of the outer pins (20) are secured to the outer holder (40). This securing of only the portions of the inner and outer pins close to the vertical sections (15, 25) while leaving the load board ends (14, 24) and device ends (18, 28) free cause the bottom cantilevers (13, 23) and top cantilevers (17, 27) to become cantilever springs.

FIG. 6 is a top view of the contact assembly of this invention that shows 3 of its 4 main components: inner pins (10), outer pins (20), and outer holder (40).

While several particularly preferred embodiments of the present invention have been described and illustrated, it should now be apparent to those skilled in the art that various changes and modifications can be made without departing from the scope of the invention. Accordingly, the following claims are intended to embrace such changes, modifications, and areas of application that are within the scope of this invention.

1. An electrical contact assembly for use in a testing apparatus, comprising:
a plurality of inner pins arranged in a row, each inner pin having a vertical section;
a plurality of outer pins arranged in a row, each outer pin having a vertical section;
an inner holder located in between said plurality of inner pins and said plurality of outer pins, said inner holder having a C-shaped cross-section, whereby an inner surface of the inner holder is adapted to receive a back side of said vertical section of said plurality of inner pins, and an outer surface of the inner holder is adapted to be received by a front side of said vertical section of said plurality of outer pins; and
an outer holder having an inner surface adapted to receive a back side of said plurality of outer pins.

2. An electrical contact assembly for use in a testing apparatus according to claim 1, wherein an adhesive is applied between said inner holder inner surface and said inner pin vertical section, such that the plurality of inner pins are joined to said inner holder.

3. An electrical contact assembly for use in a testing apparatus according to claim 1, wherein an adhesive is applied between said inner holder outer surface and said outer pin vertical section, such that the plurality of outer pins are joined to said inner holder.

4. An electrical contact assembly for use in a testing apparatus according to claim 1, wherein an adhesive is applied between said outer holder inner surface and said outer pin vertical section, so that the plurality of outer pins adhere to said outer holder.
